(19) United States
(12) Patent Application Publication
(10) Pub. No.: US 2014/0335976 A1
(43) Pub. Date: Nov. 13, 2014

(54) TRAINING SYSTEM FOR SKILL DEVELOPMENT

(71) Applicants: Ryan Michael Hiller, Manton, MI (US); Leonard Guy Morrow, JR., Manton, MI (US); Randy John Shepler, Manton, MI (US); Paul Edward Seeley, Tustin, MI (US)

(72) Inventors: Ryan Michael Hiller, Manton, MI (US); Leonard Guy Morrow, JR., Manton, MI (US); Randy John Shepler, Manton, MI (US); Paul Edward Seeley, Tustin, MI (US)

(21) Appl. No.: 14/276,530

(22) Filed: May 13, 2014

Related U.S. Application Data
(60) Provisional application No. 61/822,749, filed on May 13, 2013.

(51) Int. Cl. A63B 69/00; H05K 5/02; F16B 47/00; A63B 71/06

(52) U.S. Cl. CPC A63B 69/0071; A63B 71/0669; H05K 5/0217; F16B 47/006
USPC 473/447; 434/365

(57) ABSTRACT

A training system for skill development may include a device that includes a casing having an internal housing and an outside surface. A plurality of number displays may be enclosed within the internal housing of the casing. A circuit board may be enclosed within the internal housing of the casing and connected to the plurality of number displays. A power source may be attached to the casing. At least one upper arm comprising an upper arm joint may be attached to the outside surface of the casing. At least one lower arm comprising a lower arm joint may be attached to the outside surface of the casing. A fastening device may be attached to the at least one lower arm. The training system may be placed on a surface and be used to help develop the skill of a person keeping their eyes up while performing a function.

### CROSS-REFERENCE TO RELATED APPLICATION

This application claims the benefit of U.S. provisional application No. 61/822,749, filed May 13, 2013, the contents of which are herein incorporated by reference.

### BACKGROUND OF THE INVENTION

The present invention relates to skill development and, more particularly, to a training system for skill development.

Basketball players do not often develop the skills of looking up at their target while making a move towards the basket when dribbling and doing layups. In addition, basketball tournaments, camps, and households lack an easy visible way of keeping track of time and score.

Currently, to improve looking up while dribbling, coaches would hold up numbers with their hands to force players' heads up while they dribble and place tape on the backboard to aid in shooting layups. Other devices do not generate random numbers to aid in the development of skills and are not designed to attach to the back of a backboard.

As can be seen, there is a need for a training system for skill development that allows for a random number generator along with keeping track of time and score.

### SUMMARY OF THE INVENTION

In one aspect of the present invention, a training system for skill development comprises: a casing having an internal housing and an outside surface; a plurality of number displays enclosed within the internal housing of the casing; a circuit board enclosed within the internal housing of the casing and connected to the plurality of number displays; a power source attached to the casing; at least one upper arm having an upper arm joint attached to the outside surface of the casing; at least one lower arm having a swivel joint attached to the outside surface of the casing; and a fastening device attached to the at least one lower arm.

In another aspect of the present invention, a method for training a person to keep their head up while performing a function comprises: attaching a training system device to a surface, wherein the training system device is defined as a casing having an internal housing and an outside surface, a plurality of number displays enclosed within the internal housing of the casing, a circuit board enclosed within the internal housing of the casing and connected to the plurality of number displays, a power source attached to the casing, at least one upper arm comprising an upper arm joint attached to the outside surface of the casing, at least one lower arm comprising a lower arm joint attached to the outside surface of the casing, and a fastening device attached to the at least one lower arm; and receiving an indication from a person acknowledging a number that is presented on the training system device.

These and other features, aspects and advantages of the present invention will become better understood with reference to the following drawings, description and claims.

### BRIEF DESCRIPTION OF THE DRAWINGS

FIG. 1 is a perspective view of an exemplary embodiment of the present invention shown in use;

FIG. 2 is a front view of an exemplary embodiment of the present invention;

FIG. 3 is a front perspective view of an exemplary embodiment of the present invention;

FIG. 4 is a rear perspective view of an exemplary embodiment of the present invention;

FIG. 5 is a perspective view of a remote of an exemplary embodiment of the present invention;

FIG. 6 is a front detail view of an exemplary embodiment of the present invention;

FIG. 7 is a front detail view of an exemplary embodiment of the present invention; and

FIG. 8 is a detail rear perspective view of an exemplary embodiment of the present invention demonstrating articulation of arm components.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Broadly, an embodiment of the present invention provides a training system for skill development that may include a device that includes a casing having an internal housing and an outside surface. A plurality of number displays may be enclosed within the internal housing of the casing. A circuit board may be enclosed within the internal housing of the casing and connected to the plurality of number displays. A power source may be attached to the casing. At least one upper arm comprising an upper arm joint may be attached to the outside surface of the casing. At least one lower arm comprising a lower arm joint may be attached to the outside surface of the casing. A fastening device may be attached to the at least one lower arm. The training system may be placed on a surface and be used to help develop the skill of a person keeping their eyes up while performing a function.

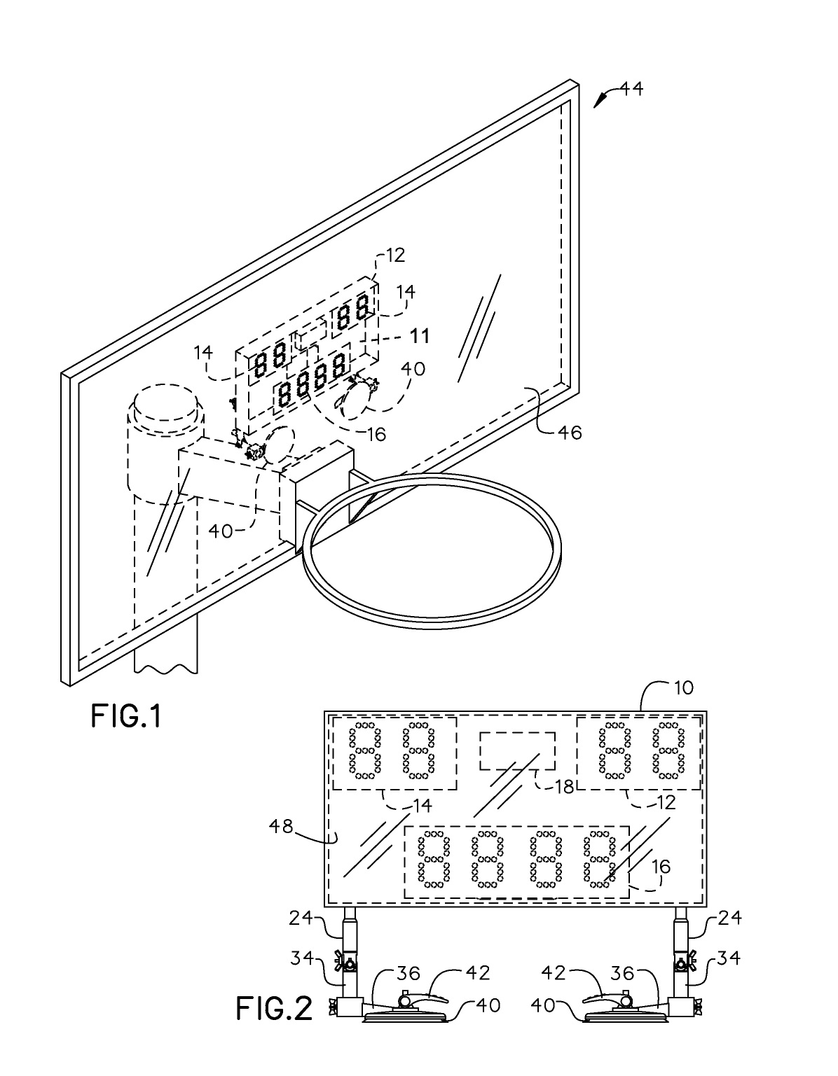

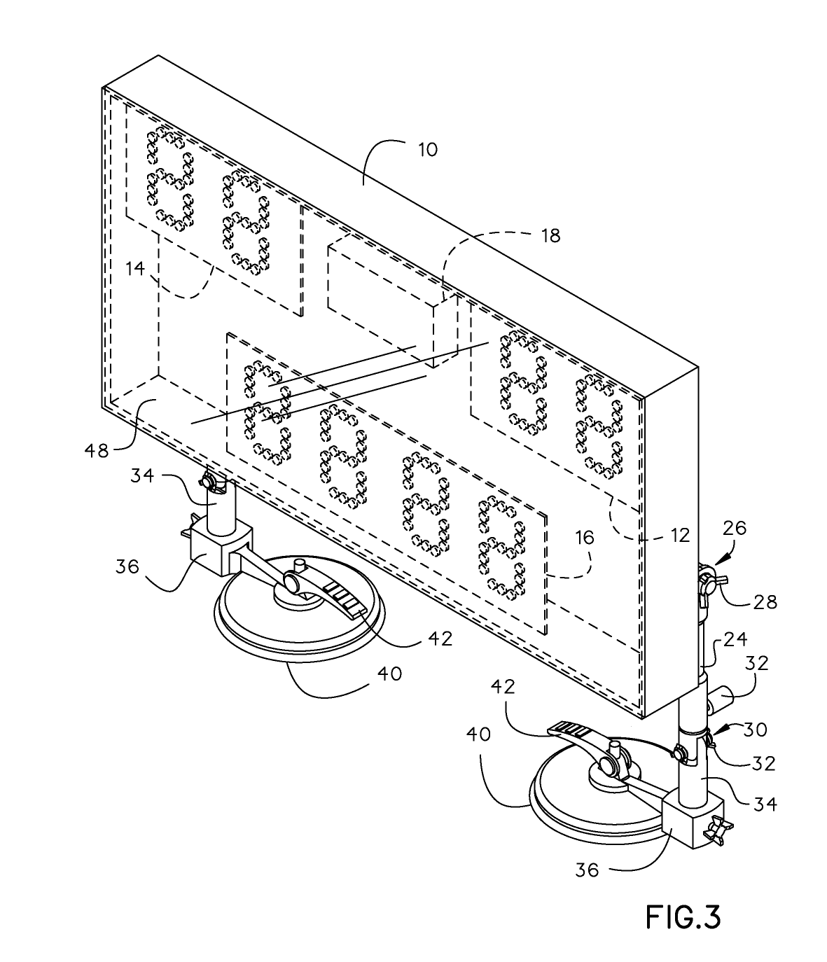

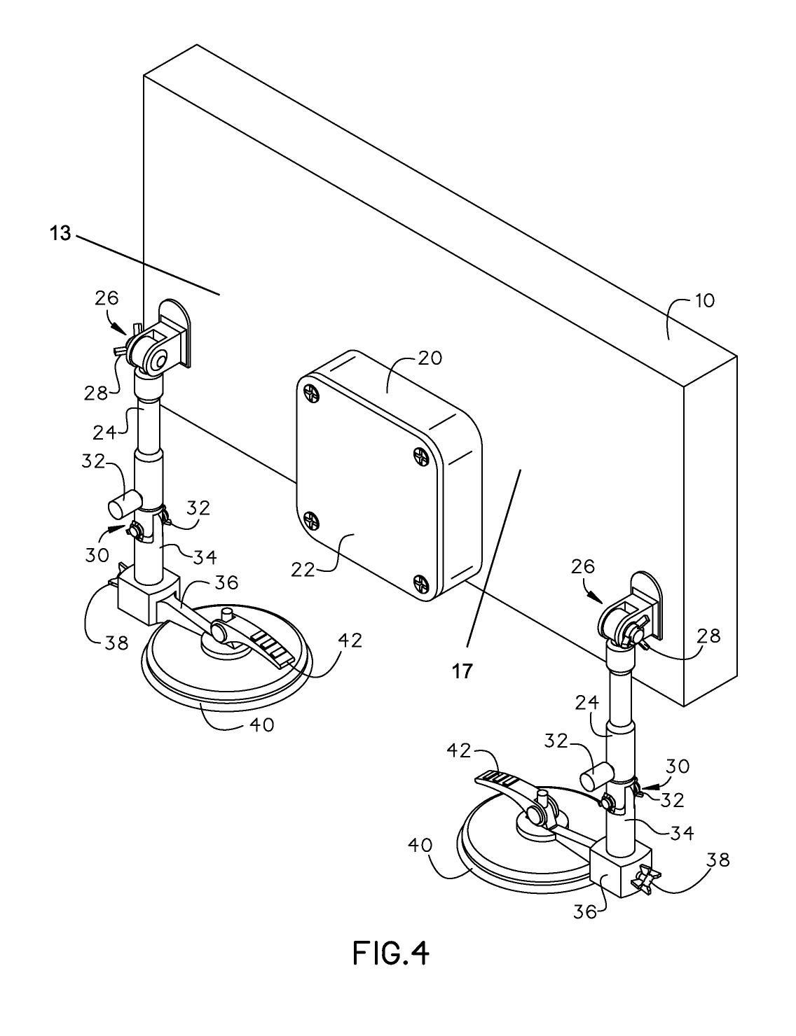

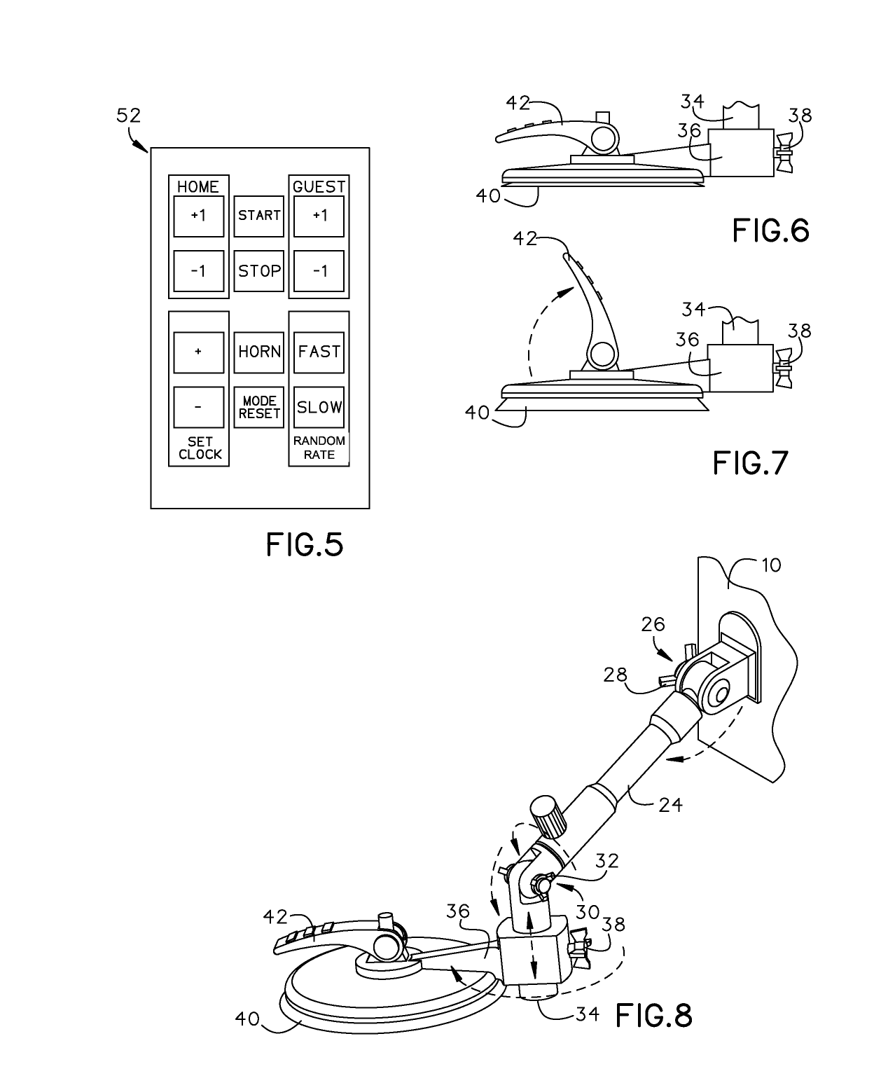

As is illustrated in FIGS. 1 through 8, a training system for skill development may include a training system device that may include a casing 10 having a rear side 17, an internal housing 11 and an outside surface 13. A plurality of number displays may be enclosed within the internal housing 11 of the casing 10. In certain embodiments, the plurality of number displays may include a right side number display 12, a left side number display 14, and a bottom number display 16. A circuit board 18 may be enclosed within the internal housing 11 of the casing 10. The circuit board 18 may be connected to the plurality of number displays. A power source may be attached to the casing 10, such as at least one battery enclosed within a battery compartment 20 with a battery compartment cover 22, or the like. In certain embodiments, the power source may be plugged into an outlet, rechargeable batteries may be used, or the like.

In certain embodiments, at least one upper arm 24 may be attached to the outside surface 13 of the casing 10. Each upper arm 24 may have an upper arm joint 26. An upper arm lock nut 28 may attach to each upper arm joint 26. The upper arm lock nut 28 may hold the position of the upper arm 24. A swivel joint 30 may attach to each upper arm 24. Each swivel joint 30 may be held in position by a swivel joint lock nut 32. A lower arm 34 may attach to the swivel joint 30. A fastening device may attach to each lower arm 34. In certain embodiments, the fastening device may at least one suction cup assembly. The at least one suction cup assembly may include at least one suction cup lever 42 removably securing at least one suction cup 40. The at least one suction cup 40 may attach to at least one suction cup bracket 36. The at least one suction cup bracket 36 may attach to the at least one lower arm 34. At least one suction cup lock fastener 38 may secure the at least one suction cup bracket 36 in place.

In certain embodiments, the casing 10 may have a clear cover 48 covering the interior housing 11. The plurality of number displays may be facing towards the clear cover 48. The fastening device may attach to a surface such as a basketball backboard glass 46 of a basketball backboard 44. A remote 52 may control the functions of the training system, such as the functions of the plurality of the number displays, the speed at which the numbers change, the start and stop of the numbers, and the like.

A method of using the training system for skill development may include the following. Attach the training system device on the backside of a basketball backboard 44. The player performing a specific function may then have to provide an indication acknowledging a number that may be presented on the training system device. The player may train the skill of keeping their head up while performing another function. In certain embodiments, the left side number display 14 and the right side number display 12 may serve as a scoreboard. A visual record of a game may be kept during the game while the training system device may be on a clear backboard such as a basketball backboard glass 46. The remote 52 may provide control over the clock function of the training system device. The remote 52 may also control the power of the device. The movement of the upper arms 24 and the lower arms 34 allow for the placement of the casing 10 in multiple positions and angles. The training system device may have the following functions, but not limited to, a countdown timer system, a count up timer system, a random number generator set to a timer, a score keeping function for at least two entities, an option to highlight home and away, an option to speed up or slow down the random numbers. The remote 52 may be able to operate the device by infra red or the like.

It should be understood, of course, that the foregoing relates to exemplary embodiments of the invention and that modifications may be made without departing from the spirit and scope of the invention as set forth in the following claims.

What is claimed is:

1. A training system for skill development comprising:
a casing having an internal housing and an outside surface;
a plurality of number displays enclosed within the internal housing of the casing;
a circuit board enclosed within the internal housing of the casing and connected to the plurality of number displays;
a power source attached to the casing;
at least one upper arm having an upper arm joint attached to the outside surface of the casing;
at least one lower arm having a swivel joint attached to the outside surface of the casing; and
a fastening device attached to the at least one lower arm.

2. The training system for skill development of claim 1, wherein the plurality of number displays is three number displays.

3. The training system for skill development of claim 1, wherein the fastening device is at least one suction cup assembly.

4. The training system for skill development of claim 3, wherein the at least one suction cup assembly comprises at least one suction cup lever removably securing at least one suction cup, wherein the at least one suction cup attaches to at least one suction cup bracket, wherein the at least one suction cup bracket attaches to the at least one lower arm, wherein at least one suction cup lock fastener secures the at least one suction cup bracket in place.

5. The training system for skill development of claim 1, further comprising a clear cover enclosing the internal housing of the casing.

6. The training system for skill development of claim 1, wherein the power source is at least one battery.

7. The training system for skill development of claim 1, further comprising a remote, wherein the remote remotely controls the functions of the training system.

8. A method for training a person to keep their head up while performing a function comprising:
attaching a training system device to a surface, wherein the training system device is defined as a casing having an internal housing and an outside surface, a plurality of number displays enclosed within the internal housing of the casing, a circuit board enclosed within the internal housing of the casing and connected to the plurality of number displays, a power source attached to the casing, at least one upper arm having an upper arm joint attached to the outside surface of the casing, at least one lower arm having a swivel joint attached to the outside surface of the casing, and a fastening device attached to the at least one lower arm; and
receiving an indication from a person acknowledging a number that is presented on the training system device.

9. The method of claim 8, wherein the indication is a verbal indication.

10. The method of claim 8, wherein the fastening device is at least one suction cup assembly.
